(19) United States
(12) Patent Application Publication
(10) Pub. No.: US 2018/0267210 A1
(43) Pub. Date: Sep. 20, 2018

(54) ANTI-REFLECTION FILM, OPTICAL COMPONENT, OPTICAL DEVICE, AND METHOD OF PRODUCING ANTI-REFLECTION FILM

(71) Applicant: SONY CORPORATION, TOKYO (JP)

(72) Inventors: TAICHI TAKEUCHI, KANAGAWA (JP); MAKOTO SATO, TOKYO (JP)

(21) Appl. No.: 15/544,082

(22) PCT Filed: Dec. 16, 2015
(86) PCT No.: PCT/JP2015/006272

§ 371 Date: Jul. 17, 2017

(30) Foreign Application Priority Data
Feb. 3, 2015 (JP) 2015-019757

(51) Int. Cl. G02B 1/118; C23C 14/30; C23C 14/34; C23C 14/08; C23C 14/14; C23C 14/58; C23F 1/02; G03F 7/00; G03F 7/16; G03F 7/20; G03F 7/36; G03F 7/09; G03F 7/004; G02B 1/115

(52) U.S. Cl. CPC G02B 1/118; G02B 1/115; C23C 14/34; C23C 14/08; C23C 14/14; C23C 14/5873; C23C 14/5846; C23F 1/02; G03F 7/0005; G03F 7/16; G03F 7/2053; G03F 7/36; G03F 7/091; G03F 7/0043; C23C 14/30

(57) ABSTRACT

[Object] To provide an anti-reflection film having a high light resistance and maintaining low reflection within wide wavelength bands, an optical component, an optical device, and a method of producing an anti-reflection film. [Solving Means] The anti-reflection film according to the invention is made of an inorganic material transparent in a visible light region, the inorganic material has a fine concave-convex structure including convex portions and concave portions each having a width equal to or smaller than a wavelength of visible light, and the concave portion has an aspect ratio of 1.5 or more.

### TECHNICAL FIELD

The present technology relates to an anti-reflection film that can be used for an optical component, an optical component including the anti-reflection film, an optical device including the anti-reflection film, and a method of producing the anti-reflection film.

### BACKGROUND ART

In recent years, a non-invasive biological observation technology using laser light, e.g., a biological visualization technology, has been focused. It is required for an optical system used in this technology to have low reflection properties within wide wavelength bands including fluorescence (visible light region) generated from a light source (near infrared light region) and a biological body.

It is difficult to satisfy the desirable properties by an AR (Anti Reflection) coating of a related art. It is necessary to provide a technology that can realize low reflection within wide wavelength bands. Accordingly, an anti-reflection film using a nano structure (Moth-eye (trademark) structure) including concaves and convexes formed in fine pitches of light wavelength order or less has been focused.

The anti-reflection film is characterized in that a reflection phenomenon itself is inhibited by using a stepwise change of an average refractive index, not by cancellation caused by interference. In principle, wavelength and angular dependencies of incident light can be decreased. It is expected to maintain low reflection within wide wavelength bands including visible light to near infrared light regions.

A variety of methods of producing a nano structure have been proposed. For example, Non-Patent Literature 1 discloses a method of producing a nano structure by using a Blu-ray disc technology. According to this method, it is possible to produce the nano structure by using an inexpensive apparatus, and a nano imprint technology is applied to decrease costs and tacts. Further, Patent Literature 1 proposes a method of producing a porous alumina layer, in which fine concave portions are uniformly distributed over a surface of an aluminum base, by using anodic oxidization.

### CITATION LIST

### Patent Literature

Patent Literature 1: Japanese Patent Application Laid-open No. 2008-38237

### Non-Patent Literature

Non-Patent Literature 1: Sohmei Endoh, Kazuya Hayashibe, “Nanomold Fabrication, and Nanoimprint Anti-reflection Structures utilized Blu-ray Disc Technology”, The 7th International Conference on Nanoimprint, and Nanoprint Technology

### DISCLOSURE OF INVENTION

### Technical Problem

However, according to the method of producing a nano structure of Non-Patent Literature 1, a maximum aspect ratio is about 1.5, and it is therefore difficult to realize low reflection to light within wide wavelength bands. Further, according to the method described in Patent Literature 1, an aspect ratio of a mold is easily increased, but a practical aspect ratio is limited to about 1.5, similar to Non-Patent Literature 1.

Furthermore, these methods are based on the nano imprint technology using hardening resin. There are problems such as yellowing due to absorption by the resin. Therefore, these method are unsuitable for applying to heat resistant and light resistant optical components (for example, optical components for laser, or the like).

The present technology is made in view of the above-mentioned circumstances, and it is an object of the present technology to provide an anti-reflection film having a high light resistance and maintaining low reflection within wide wavelength bands, an optical component, an optical device, and a method of producing an anti-reflection film.

### Solution to Problem

In order to achieve the object, an anti-reflection film according to an embodiment of the present technology is made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

With this configuration, the fine concave-convex structure of the anti-reflection film is made of an inorganic material, and may have a high light resistance. Also, since the aspect ratio of the concave portion is 1.5 or more, low reflection may be maintained within wide wavelength bands. Thus, the present technology can provide an anti-reflection film having a high light resistance and maintaining low reflection within wide wavelength bands. It should be noted that in a case where the aspect ratio of the concave portion is 4 or more, it is desirably widen the wavelength bands for low reflection.

The anti-reflection film may have a reflectance for visible light and near-infrared rays of less than 0.5%.

With this configuration, it is possible to provide the anti-reflection film having a small reflectance for visible light and near-infrared rays

The concave portions may be pores arrayed among the convex portions, and the aspect ratio may be a ratio of a diameter of an opening to a depth of each of the pores.

With this configuration, in a case where the aspect ratio is high, the pore can have the high ratio of the diameter of the opening to the depth.

The transparent inorganic material may be selected from materials capable of being dry-etched.

With this configuration, it is possible to form the fine concave-convex structure by dry etching.

The transparent inorganic material may be capable of being dry-etched, and may be selected from the group consisting of SiO₂, HfO₂, Al₂O₃, ITO, MgF₂, TiO₂, CaF₂, and the like.

By using the transparent inorganic material including the above-described materials, it is possible to provide the anti-reflection film having a small reflectance to which laser is applicable.

In order to achieve the object, an optical component according to an embodiment of the present technology includes a base, and an anti-reflection film.

The anti-reflection film is laminated on the base, is made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

In order to achieve the object, an optical device according to an embodiment of the present technology includes a laser light source, and an optical component.

The optical component is an optical component disposed in an optical system of the laser light source, the optical component including a base, and an anti-reflection film laminated on the base, the anti-reflection film being made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

In order to achieve the object, a method of producing an anti-reflection film, including laminating, on a base, a transparent material layer made of an inorganic material transparent in a visible light region, laminating, on the transparent inorganic material, a metal material layer made of a metal material, laminating, on the metal material layer, an inorganic material layer made of incomplete oxide of transition metal, irradiating the inorganic material layer with laser to process a part of the inorganic material, developing the inorganic material layer and removing the processed part to form a first etching mask, etching the metal material layer using the first etching mask to form a second etching mask, and etching the transparent material layer using the second etching mask to form a fine concave-convex structure.

By etching using the first etching mask and etching using the second etching mask in combination, it is possible to deeply etch the transparent material layer deep, and to form the fine concave-convex structure having the high aspect ratio. With this, it is possible to provide the anti-reflection film having a small reflectance for visible light and near-infrared rays.

In the method of producing an anti-reflection film, the step of forming the second etching mask may include etching the metal material layer on the condition that an etching selection ratio of the metal material layer to the first etching mask is 0.3 or more.

This configuration ensures the etching selection ratio to the metal material layer.

In the method of producing an anti-reflection film, the step of forming the second etching mask may include chemically etching the metal material layer using etching gas that selectively reacts with the metal material.

With this configuration, the etching selection ratio to the metal material layer is improved, and the metal material layer can be etched more deeply.

In the method of producing an anti-reflection film, the step of forming the second etching mask may include selecting the metal material having an atomic weight smaller than an atomic weight of the inorganic material and physically etching the metal material.

With this configuration, since the atomic weight of the metal material layer is smaller than the atomic weight of the inorganic material layer, the sputtering rate of the metal material layer obtainable by ion bombardment exceeds the rate of the inorganic material layer. This ensures the etching selection ratio to the metal material layer.

In the method of producing an anti-reflection film, the step of forming the fine concave-convex structure may include etching the transparent material layer on the condition that an etching selection ratio of the transparent material layer to the second etching mask is 15 or more.

With this configuration, it is possible to improve the etching selection ratio to the transparent material layer and to deeply etch the transparent material layer. Accordingly, it is possible to form the fine concave-convex structure having the high aspect ratio.

In the method of producing an anti-reflection film, the step of forming the second etching mask may include physically etching, and the step of forming the fine concave-convex structure may include chemically etching.

In the step of forming the fine concave-convex structure, the second etching mask formed by physical etching or chemical etching is used. Thus, the selection ratio may be increased by using the difference in the etching rates of the metal material layer and the transparent material layer.

In the method of producing an anti-reflection film, the step of forming the second etching mask may include reactive ion etching.

By the reactive ion etching, the metal material layer can be etched with high accuracy, and the second etching mask can be formed.

In the method of producing an anti-reflection film, the inorganic material may be transition metallic heat sensitive resist made of incomplete oxide of transition metal.

With this, only the portions, which are exposed by laser and exceed a thermal reaction threshold, become soluble to an alkaline developing solution, and it is possible to form a desirable pattern on the inorganic material layer.

### ADVANTAGEOUS EFFECTS OF INVENTION

As described above, according to the present technology, there are provided an anti-reflection film having a high light resistance and maintaining low reflection within wide wavelength bands, an optical component, an optical device, and a method of producing the anti-reflection film of Drawings

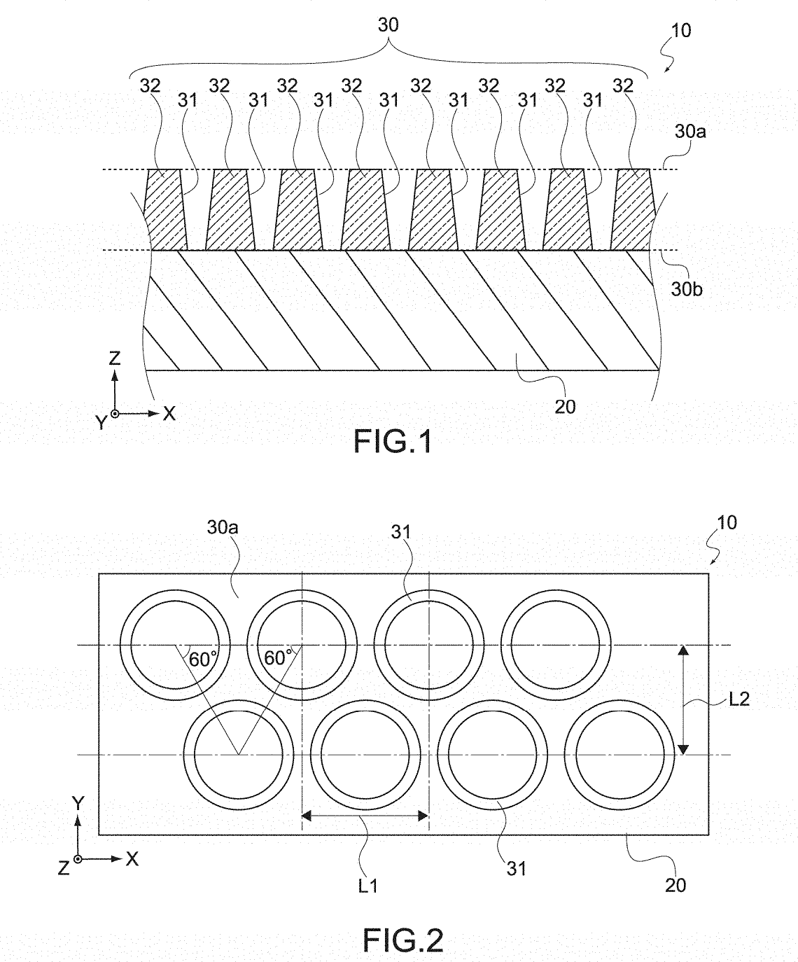

FIG. 1 is a diagram schematically showing an anti-reflection structure according to an embodiment of the present technology.

FIG. 2 is a plan view of the anti-reflection structure.

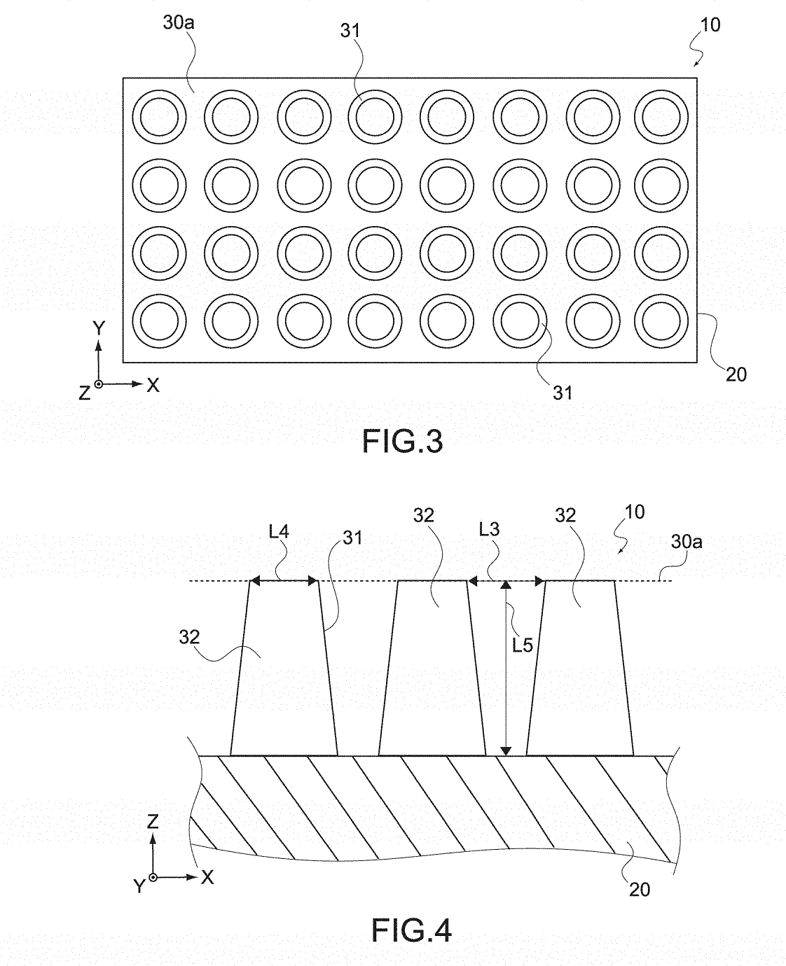

FIG. 3 is a diagram schematically showing a variation of arrangement of the anti-reflection structure.

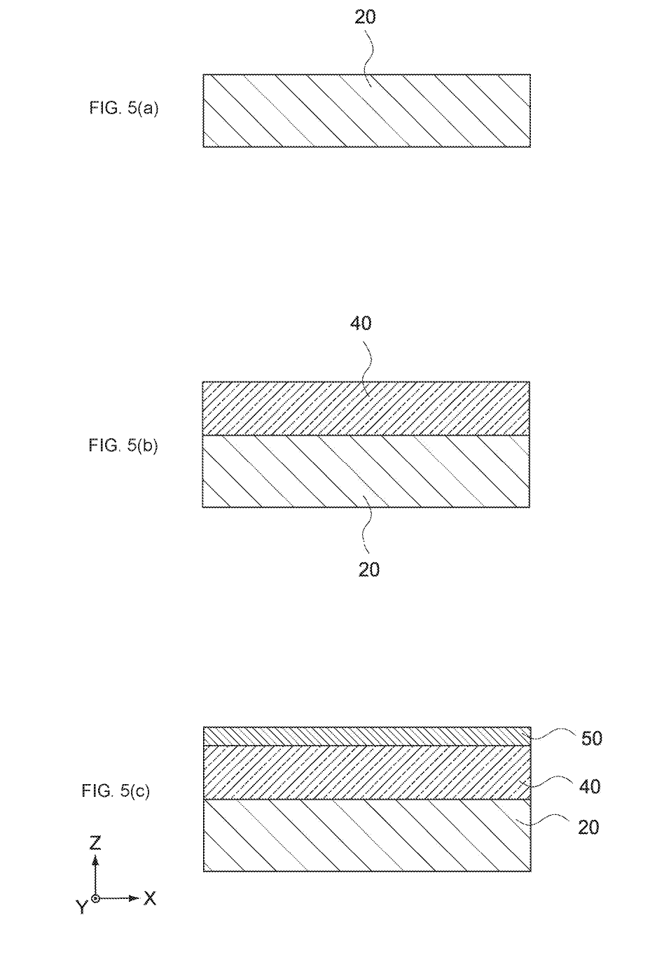

FIG. 4 is a view showing the anti-reflection structure in an enlarged state.

FIG. 5 is diagrams schematically showing production processes of the anti-reflection film according to the embodiment of the present technology.

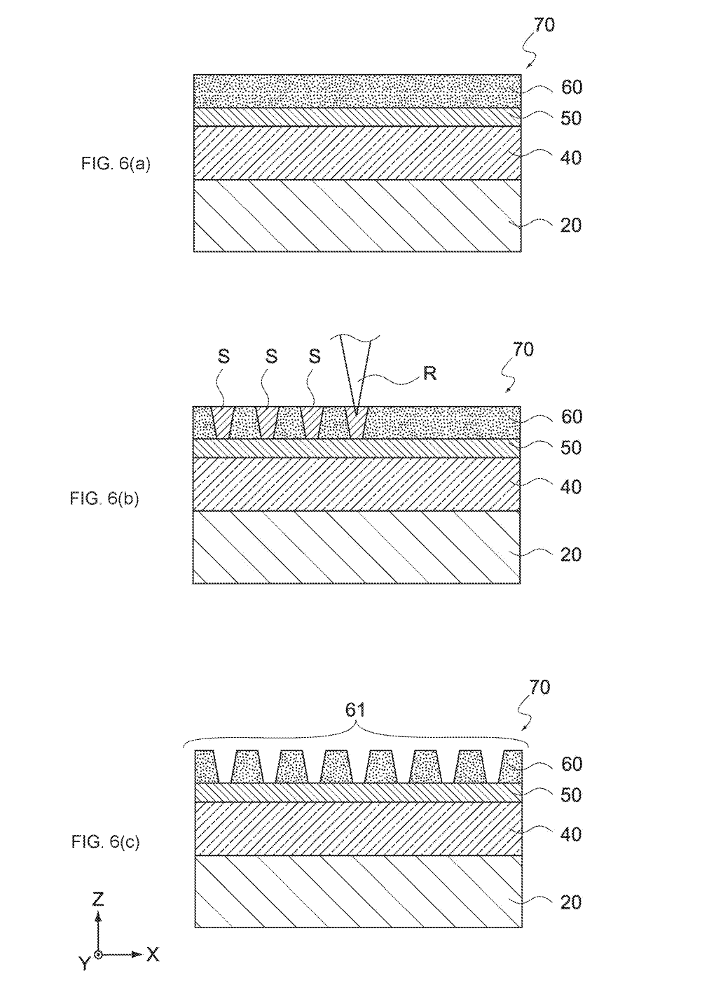

FIG. 6 is diagrams showing production processes of the anti-reflection film.

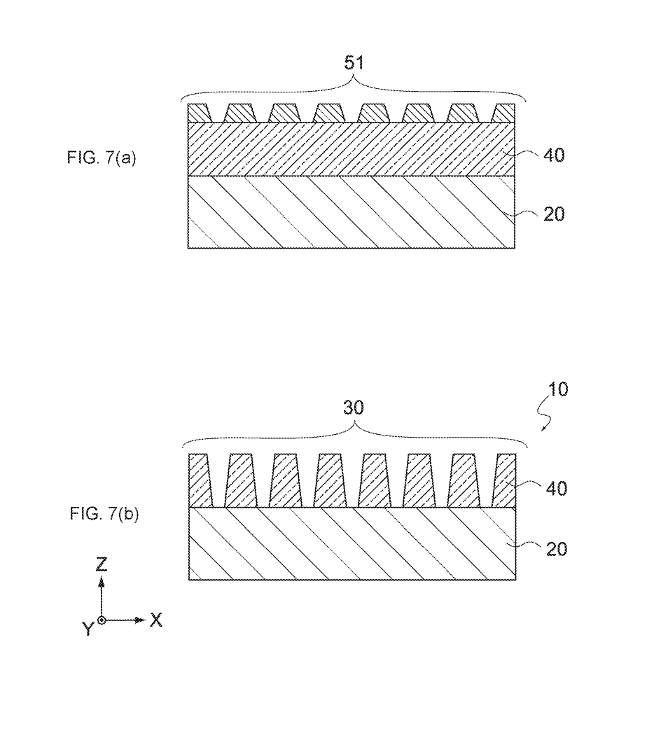

FIG. 7 is diagrams showing production processes of the anti-reflection film.

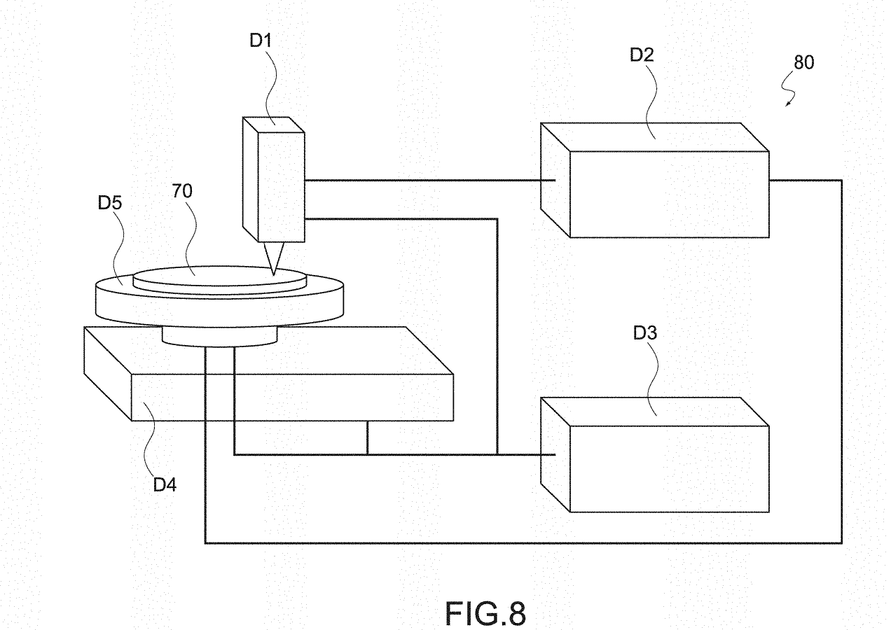

FIG. 8 is a diagram schematically showing a laser exposure apparatus according to the embodiment of the present technology.

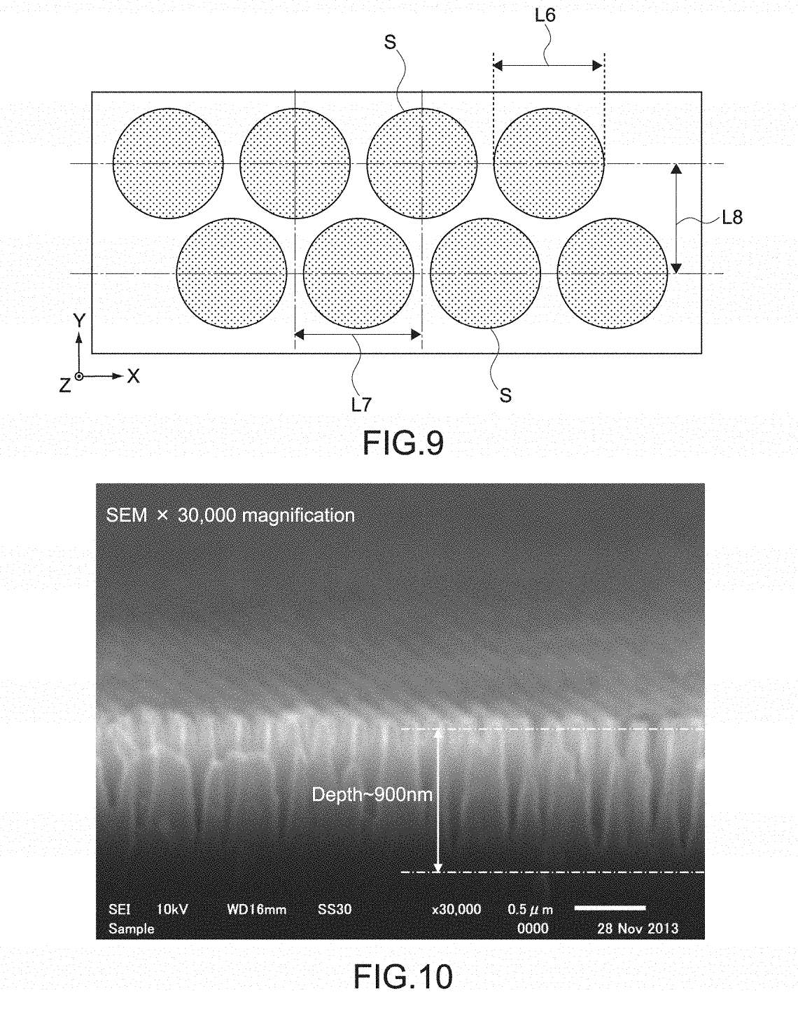

FIG. 9 is a diagram schematically showing a workpiece according to the embodiment of the present technology.

FIG. 10 is an image of the anti-reflection structure according to the embodiment of the present technology captured by a scanning electron microscope (SEM).

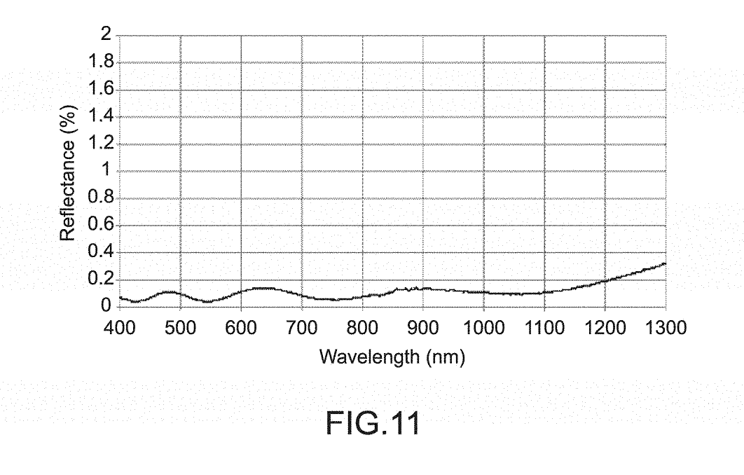

FIG. 11 is a diagram showing reflectance properties of the anti-reflection film according to the embodiment of the present technology.

### MODE(S) FOR CARRYING OUT THE INVENTION

Hereinafter, an embodiment of the present technology will be described with reference to the drawings.

[Configuration of Anti-Reflection Structure]

FIG. 1 and FIG. 2 are diagrams schematically showing an anti-reflection structure 10 according to an embodiment of the present technology. FIG. 1 is a cross-sectional view, and FIG. 2 is a plan view. In the following diagrams, the X direction, the Y direction, and the Z direction are three directions being orthogonal to each other.

As shown in FIG. 1, the anti-reflection structure 10 includes a base 20 and an anti-reflection film 30.

The base 20 supports the anti-reflection film 30. As shown in FIG. 1 and FIG. 2, the base 20 has a flat-plate form, but may have a film-like or roll-like form. Further, the surface form of the base 20 is not limited to flat, but the base 20 may have a spherical surface, a free-form (curved) surface, or the like.

The base 20 is made of a light transmissive material, for example, a transparent material such as bulk synthetic quartz, SiO₂, and an crystalline material. Further, the base 20 may not be necessarily made of the light transmissive material.

In addition, the base 20 may be an optical component such as a lens, a half mirror, a prism, a light guide, a film, and a diffraction grating.

As shown in FIG. 1, the anti-reflection film 30 is disposed on the base 20 and includes concave portions 31 and convex portions 32. The anti-reflection film 30 has a plurality of concave portions 31 arrayed among the convex portions 32. Thus, as shown in FIG. 1, a fine concave-convex structure is provided.

Further, as shown in FIG. 1, the surface in parallel with a layer plane direction (X-Y directions) of the anti-reflection film 30 is denoted as a front surface 30a and the opposite surface is denoted as a rear surface 30b. Each concave portion 31 is formed such that the depth direction is the thickness direction (Z direction) of the anti-reflection film 30 from the front surface 30a to the rear surface 30b.

As shown in FIG. 1 and FIG. 2, each concave portion 31 has a circular opening, and has the shape having a gradually reducing diameter as the depth is increased. In addition, the shape of each concave portion 31 is not limited to that shown in FIG. 1 and FIG. 2. For example, the shape of the opening is not limited to a circle, and may be a square, a polygon, or the like.

As shown in FIG. 2, the openings of the concave portions 31 are arranged most densely on the front surface 30a. Specifically, the angle between the lines connecting the centers of the adjacent concave portions 31 is 60°. Also, as shown in FIG. 2, the interval L1 or L2 between the concave portions 31 is approximately several hundreds nm, where L1 is defined as an interval between the centers of the adjacent concave portions 31 in the X direction, and L2 is defined as an interval between the centers of the adjacent concave portions 31 in the Y direction.

The arragement of the openings of the concave portions 31 formed on the front surface 30a is not limited to the arrangement shown in FIG. 2, and may be arbitrarily determined. FIG. 3 shows a variation of the arrangement of the openings of the concave portions 31. As shown in FIG. 3, the arrangement of the openings of the concave portions 31 may be a matrix, for example.

As shown in FIG. 1 and FIG. 2, the convex portions 32 may be positioned between the adjacent concave portions 31. The forms of the convex portions 32 are not limited, and may correspond to the forms of the concave portions 31.

FIG. 4 is a view showing the anti-reflection structure 10 in an enlarged state. As shown in FIG. 4, the lengths L3 and L4 are equal to or smaller than a wavelength of visible light, where L3 is defined as a width of the opening of each concave portion 31, and L4 is defined as a width of each convex portion 32 at a front surface 30a side. Further, an aspect ratio of each concave portion 31 is a ratio of L3 to L5, where L5 is defined as a depth. As described later, the aspect ratio of each concave portion 31 is 1.5 or more, and desirably 4 or more according to this embodiment.

The anti-reflection film 30 is made of a material transparent in a visible light region. The material of the anti-reflection film 30 is desirably has a high light resistance to laser light. Examples include SiO₂, HfO₂, Al₂O₃, ITO, MgF₂, TiO₂, CaF₂, Na₂O—B₂O₃—SiO₂, and the like.

[Method of Producing Anti-Reflection Film]

A method of producing the anti-reflection film 30 according to this embodiment will be described. It should be noted that the following production method is described by way of example.

It is also possible to produce the anti-reflection film 30 by a method different from the following method. FIG. 5 to FIG. 7 are diagrams schematically showing production processes of the anti-reflection film 30.

FIG. 5(a) shows the base 20 of the anti-reflection structure 10. As shown in FIG. 5(b), a transparent material layer 40 made of the material of the above-described anti-reflection film 30 is laminated on the base 20. Non-limiting examples of the suitable method of laminating the transparent material layer 40 include gas phase methods such as a sputtering method, a pulse laser deposition (PLD) method, and an electron beam vapor deposition method. In addition, the transparent material layer 40 has a film thickness of about several μm.

Next, as shown in FIG. 5(c), the metal material layer 50 is laminated on the transparent material layer 40 laminated on the base 20. Non-limiting examples of the suitable method of laminating the metal material layer 50 include gas phase methods such as a sputtering method, a pulse laser deposition (PLD) method, and an electron beam vapor deposition method. In addition, the metal material layer 50 has a film thickness of about several tens nm.

The material of the metal material layer 50 is pure metal such as Cu, Ni, Cr, Ag, Pd, Fe, Sn, Pb, Pt, Ir, Rh, Ru, Al, and Ti, or an alloy thereof, and is not especially limited.

Furthermore, as shown in FIG. 6(a), the inorganic material layer 60 is laminated on the metal material layer 50. Non-limiting examples of the suitable method of laminating the metal material layer 50 include gas phase methods such as a sputtering method, a pulse laser deposition (PLD) method, and an electron beam vapor deposition method. In addition, the inorganic material layer 60 has a film thickness of about several tens nm. Hereinafter, a laminate including the transparent material layer 40, the metal material layer 50, and the inorganic material layer 60 laminated on the base 20 is called as a workpiece 70.

The inorganic material layer 60 is made of an inorganic material of incomplete oxide of transition metal. Examples of the inorganic material include transition metallic heat sensitive resist. In addition, as the transition metal, Ti, V, Cr, Mn, Fe, Nb, Cu, Ni, Co, Mo, Ta, W, Zr, Ru, Ag, or the like may be used. It should be noted that the inorganic material is not especially limited as long as the inorganic material is photosensitive, so-called thermally recordable, with a heat reaction caused by laser light irradiation.

Next, as shown in FIG. 6(b), the inorganic material layer 60 is irradiated with laser light R. In this case, only the portions of the inorganic material layer 60, which are heated by the laser light R and exceed a thermal reaction threshold, become soluble to an alkaline developing solution. In FIG. 6(b), processed parts S represent the alkali-soluble portions of the inorganic material layer 60. It should be noted that a laser exposure apparatus available for irradiating the inorganic material layer 60 with the laser light R will be described later.

Next, the exposed workpiece 70 is developed with the alkaline developing solution. As a result, only the processed parts S are dissolved in the alkaline developing solution, and, as shown in FIG. 6(c), a plurality of the concave portions are formed in the inorganic material layer 60. Hereinafter, the inorganic material layer, in which the plurality of concave portions are formed, is denoted as a first etching mask 61.

Next, the metal material layer 50 is etched by using the first etching mask 61. Thus, as shown in FIG. 7(a), the plurality of concave portions are formed in the metal material layer 50. Here, it is desirable that a selection ratio of the metal material layer 50 to the first etching mask 61 be 0.3 or more, and more desirably 0.5 or more. This ensures the etching selection ratio to the metal material layer 50. The metal material layer 50 is etched by physical etching or chemical etching, which will be described later in detail. Hereinafter, the metal material layer, in which the plurality of concave portions are formed, is denoted as a second etching mask 51.

Next, the transparent material layer 40 is etched by using the second etching mask 51. Thus, as shown in FIG. 7(b), the plurality of concave portions are formed in the transparent material layer 40. Here, it is desirable that a selection ratio of the transparent material layer 40 to the second etching mask 51 be 15 or more. This ensures the etching selection ratio to the transparent material layer 40, which enables the transparent material layer 40 to be etched more deeply. The transparent material layer 40 is etched by chemical etching, which will be described later in detail. It should be noted that, as shown in FIG. 7(b), the transparent material layer, in which the plurality of concave portions are formed, corresponds to the anti-reflection film 30.

The anti-reflection film 30 is produced in the above-mentioned manner.

[Formation of Second Etching Mask]

The second etching mask 51 is formed by chemical etching or physical etching. As the chemical etching, RIE (Reactive Ion Etching) may be employed, which uses a type of gas that is easily reacted with the metal material layer 50 and is difficult to react with the first etching mask 61. For example, in a case where the metal material layer 50 is made of Al and the first etching mask 61 is made of a W material (incomplete oxide of W), the RIE is performed by using chlorine gas (Cl₂) as the type of gas. Since the etching selection ratio to the metal material layer 50 is improved, the metal material layer 50 can be etched more deeply.

As the chemical etching, not only the above-described RIE but also a dry etching method such as reactive gas etching, reactive ion beam etching, and reactive laser beam etching may be employed, for example.

The physical etching may be performed by using inactive gas in a case where an atomic weight of the metal material layer 50 is smaller than an atomic weight of the inorganic material layer 60. Thus, at the time of etching the metal material layer 50 by using the first etching mask 61 formed of the inorganic material layer 60, a sputtering rate of the metal material layer 50 obtainable by ion bombardment exceeds the rate of the inorganic material layer 60. This ensures the etching selection ratio to the metal material layer 50.

As the physical etching, an ion milling method using Ar gas as the inert gas may be employed, for example. This allows the selection ratio of the metal material layer 50 to the first etching mask 61 to be 0.3 or more. It should be noted that the above-described physical etching is not limited to the ion milling method.

[Etching of Transparent Material Layer]

The transparent material layer 40 may be etched by chemical etching that is reacted with the transparent material layer 40 and is difficult to react with the second etching mask 51. Specifically, RIE may be performed by using fluorine gas such as CF₄, C₄F₈, and CHF₃ as etching gas. This allows the selection ratio of the transparent material layer 40 to the second etching mask 51 to be improved.

In a case where the transparent material layer 40 is made of SiO₂ and the second etching mask 51 is made of Ni, the transparent material layer 40 is etched by using CHF₃ gas as the type of gas, which results in the selection ratio of the transparent material layer 40 to the second etching mask 51 of 30 or more. Since the transparent material layer 40 is thus etched more deeply, the aspect ratio of the concave portion 31 may be increased. In addition, since the transparent material layer 40 is made of SiO₂, it is possible to provide the anti-reflection film 30 having an excellent light resistance and a small reflectance.

Further, since the second etching mask 51 formed by physical etching or chemical etching is used, the selection ratio may be increased by using the difference in the etching rates of the metal material layer 50 and the transparent material layer 40.

[Laser Exposure Apparatus]

FIG. 8 is a diagram schematically showing a laser exposure apparatus 80 according to this embodiment. The workpiece 70 according to this embodiment is processed by the laser exposure apparatus 80 shown in FIG. 8. As shown in FIG. 8, the laser exposure apparatus 80 includes a laser exposure unit D1, a signal generator D2, a controller D3, a slide D4, and a rotor D5.

The laser exposure unit D1 receives signals fed from the signal generator D2 and generates laser. The signal generator D2 receives information about the slide D4 and the rotor D5 fed from the controller D3, generates signals at a predetermined timing, and feeds the laser exposure unit D1 with the signals.

The controller D3 controls driving of the slide D4 and rotor D5 and feeds the signal generator D2 with the information about the driving statuses (such as a slide position and a rotation angle). By the control of the controller D3, the slide D4 slides the rotor D5. The rotor D5 supports the workpiece 70 and rotates the workpiece 70 by the control of the controller D3.

The laser exposure apparatus 80 processes the workpiece 70 by a PTM (Phase Transition Mastering) method. Specifically, the laser exposure apparatus 80 performs exposure by collecting collimated light from a light source via an objective lens, fixing a focal position on a surface or inside of an object to be exposed, and rotating or sliding the object.

In this manner, the anti-reflection film 30 may be mass-produced by a simple process without the need for an expensive apparatus that performs electron beam exposure or the like. As a result, facilities costs can be significantly reduced. In addition, as the light source of the laser exposure apparatus 80, an inexpensive laser diode may be employed. It should be noted that the laser exposure apparatus 80 of this embodiment is not limited to the configuration shown in FIG. 8.

It should be noted that in a case where the laser exposure apparatus 80 exposes the object to be exposed while the object to be exposed is rotated, a feed pitch in a radial direction corresponds to the interval L2 between the centers of the concave portions 31 in the Y direction, and a feed pitch in a rotation direction corresponds to the interval L1 between the centers of the concave portions 31 in the X direction (see FIG. 2).

[Optical Device]

The anti-reflection structure 10 of this embodiment can be mounted to a variety of optical devices such as a microscope, a camera, and a telescope. In particular, since the anti-reflection structure 10 has a high resistance to laser light, the anti-reflection structure 10 can be desirably used for the optical device including the laser light source. It should be noted that the optical devices, to which the anti-reflection structure 10 can be mounted, are not limited to the above.

### Modification Embodiments

In the anti-reflection film 30 of this embodiment, in a case where adhesion between the base 20 and the transparent material layer 40 is low, an adhesion layer may be provided between the base 20 and the transparent material layer 40. In this case, the adhesion layer desirably has a thickness of 100 nm or less. Examples of the material of the adhesion layer include Al₂O₃, Y₂O₃, Ti₂O₃, TiO, TiO₂, and the like. Furthermore, the anti-reflection film 30 has a configuration that includes the convex portions among the plurality of concave portions independent of each other, but is not limited thereto. The anti-reflection film 30 may have a configuration that includes concave portions among a plurality of convex portions independent of each other.

### EXAMPLE

Hereinafter, an example of the present technology will be described.

The anti-reflection structure described in the embodiment was produced and evaluated.

First, a transparent material layer having a thickness of 1.5 μm was laminated on a base by electron beam vapor deposition (see FIG. 5(b)). Next, a metal material layer made of Ni having a thickness of 30 nm was laminated on the transparent material layer by sputtering (see FIG. 5(c)). Next, an inorganic material layer made of a W material (incomplete oxide of W) having a thickness of 90 nm was laminated on the metal material layer by sputtering. Thus, a workpiece was provided (see FIG. 6(a)).

Next, the workpiece was exposed as described below using the laser exposure apparatus described in the above embodiment.

FIG. 9 is a diagram schematically showing the workpiece viewed from the thickness direction (see FIG. 6(b)). FIG. 9 shows the processed parts S processed by the step of exposing the inorganic material layer. The distance L6 shown in FIG. 9 is a diameter of each processed part S, and corresponds to the width L3 of the opening of each concave portion described in the embodiment (see FIG. 4).

As shown in FIG. 9, the inorganic material layer of the workpiece was exposed so that the processed parts S were arranged most densely. In this case, the distance L6 was 200 nm. Specifically, as shown in FIG. 9, exposure was performed such that the L7 was 231 nm and the L8 was 200 nm where the L7 denoted the interval in the X direction and the L8 denoted the interval in the Y direction between the centers of the adjacent processed parts S.

Next, the exposed workpiece was developed with the alkaline developing solution as described in the embodiment, and the first etching mask was formed. Next, the metal material layer was etched by using the first etching mask to form the second etching mask, and the transparent material layer was etched by using the second etching mask to provide the anti-reflection structure.

An image of the anti-reflection structure produced as described above was captured by a scanning electron microscope (SEM). FIG. 10 shows the captured image.

As shown in FIG. 10, the depth of each concave portion was 900 nm and the aspect ratio (900 nm/L6) of each concave portion was 4.5.

Next, reflectance properties of the anti-reflection film of the anti-reflection structure were determined. FIG. 11 is a diagram showing the reflectance of the anti-reflection film.

As shown in FIG. 11, the anti-reflection film of the anti-reflection structure had the reflectance of less than 0.5% to light in the wavelength of 400 nm to 1300 nm. From the result, it was confirmed that the anti-reflection film 30 according to the present technology can realize low reflection to light within wide wavelength bands including a visible light region to a near infrared light region.

As above, while the embodiment of the present technology has been described, the present technology is not limited thereto. Various alternations can be made on the basis of the technical ideas of the present technology.

The present technology may also employ the following configurations.

(1) An anti-reflection film,

the anti-reflection film being made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

(2) The anti-reflection film according to (1), in which

the anti-reflection film has a reflectance for visible light and near-infrared rays of less than 0.5%.

(3) The anti-reflection film according to (1) or (2), in which

the concave portions are pores arrayed among the convex portions, and

the aspect ratio is a ratio of a diameter of an opening to a depth of each of the pores.

(4) The anti-reflection film according to any one of (1) to (3), in which

the transparent inorganic material is selected from materials capable of being dry-etched.

(5) The anti-reflection film according to any one of (1) to (4), in which

the transparent inorganic material is selected from the group consisting of SiO₂, HfO₂, Al₂O₃, ITO, MgF₂, TiO₂, and CaF₂.

(6) An optical component, including:

a base; and

an anti-reflection film laminated on the base, the anti-reflection film being made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

(7) An optical device, including:

a laser light source; and

an optical component disposed in an optical system of the laser light source, the optical component including

a base, and

an anti-reflection film laminated on the base, the anti-reflection film being made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

(8) A method of producing an anti-reflection film, including:

laminating, on a base, a transparent material layer made of an inorganic material transparent in a visible light region;

laminating, on the transparent inorganic material, a metal material layer made of a metal material;

laminating, on the metal material layer, an inorganic material layer made of incomplete oxide of transition metal;

irradiating the inorganic material layer with laser to process a part of the inorganic material;

developing the inorganic material layer and removing the processed part to form a first etching mask;

etching the metal material layer using the first etching mask to form a second etching mask; and

etching the transparent material layer using the second etching mask to form a fine concave-convex structure.

(9) The method of producing an anti-reflection film according to (8), in which

the step of forming the second etching mask includes etching the metal material layer on the condition that an etching selection ratio of the metal material layer to the first etching mask is 0.3 or more.

(10) The method of producing an anti-reflection film according to (8) or (9), in which

the step of forming the second etching mask includes chemically etching the metal material layer using etching gas that selectively reacts with the metal material.

(11) The method of producing an anti-reflection film according to any one of (8) to (10), in which

the step of forming the second etching mask includes selecting the metal material having an atomic weight smaller than an atomic weight of the inorganic material and physically etching the metal material.

(12) The method of producing an anti-reflection film according to any one of (8) to (11), in which

the step of forming the fine concave-convex structure includes etching the transparent material layer on the condition that an etching selection ratio of the transparent material layer to the second etching mask is 15 or more.

(13) The method of producing an anti-reflection film according to any one of (8) to (12), in which

the step of forming the second etching mask includes physically etching the transparent material layer, and

the step of forming the fine concave-convex structure includes chemically etching the transparent material layer.

(14) The method of producing an anti-reflection film according to any one of (8) to (13), in which the step of forming the second etching mask includes reactive ion etching the transparent material layer.

(15) The method of producing an anti-reflection film according to any one of (8) to (14), in which

the inorganic material is transition metallic heat sensitive resist made of incomplete oxide of transition metal.

### REFERENCE SIGNS LIST

10 anti-reflection structure
20 base
30 anti-reflection film
31 concave portion
32 convex portion
40 transparent material layer
50 metal material layer
51 second etching mask
60 inorganic material layer
61 first etching mask

1. An anti-reflection film,
the anti-reflection film being made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

2. The anti-reflection film according to claim 1, wherein
the anti-reflection film has a reflectance for visible light and near-infrared rays of less than 0.5%.

3. The anti-reflection film according to claim 1, wherein
the concave portions are pores arrayed among the convex portions, and
the aspect ratio is a ratio of a diameter of an opening to a depth of each of the pores.

4. The anti-reflection film according to claim 1, wherein
the transparent inorganic material is selected from materials capable of being dry-etched.

5. The anti-reflection film according to claim 1, wherein
the transparent inorganic material is selected from the group consisting of SiO₂, HfO₂, Al₂O₃, ITO, MgF₂, TiO₂, and CaF₂.

6. An optical component, comprising:
a base; and
an anti-reflection film laminated on the base, the anti-reflection film being made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

7. An optical device, comprising:
a laser light source; and
an optical component disposed in an optical system of the laser light source, the optical component including
a base, and
an anti-reflection film laminated on the base, the anti-reflection film being made of an inorganic material transparent in a visible light region, the inorganic material having a fine concave-convex structure including convex portions and concave portions each having a width equal to or smaller than a wavelength of visible light, and the concave portion having an aspect ratio of 1.5 or more.

8. A method of producing an anti-reflection film, comprising:
laminating, on a base, a transparent material layer made of an inorganic material transparent in a visible light region;
laminating, on the transparent inorganic material, a metal material layer made of a metal material;
laminating, on the metal material layer, an inorganic material layer made of incomplete oxide of transition metal;
irradiating the inorganic material layer with laser to process a part of the inorganic material;
developing the inorganic material layer and removing the processed part to form a first etching mask;
etching the metal material layer using the first etching mask to form a second etching mask; and
etching the transparent material layer using the second etching mask to form a fine concave-convex structure.

9. The method of producing an anti-reflection film according to claim 8, wherein
the step of forming the second etching mask includes etching the metal material layer on the condition that an etching selection ratio of the metal material layer to the first etching mask is 0.3 or more.

10. The method of producing an anti-reflection film according to claim 8, wherein
the step of forming the second etching mask includes chemically etching the metal material layer using etching gas that selectively reacts with the metal material.

11. The method of producing an anti-reflection film according to claim 8, wherein
the step of forming the second etching mask includes selecting the metal material having an atomic weight smaller than an atomic weight of the inorganic material and physically etching the metal material.

12. The method of producing an anti-reflection film according to claim 8, wherein
the step of forming the fine concave-convex structure includes etching the transparent material layer on the condition that an etching selection ratio of the transparent material layer to the second etching mask is 15 or more.

13. The method of producing an anti-reflection film according to claim 8, wherein
the step of forming the second etching mask includes physically etching the transparent material layer, and
the step of forming the fine concave-convex structure includes chemically etching the transparent material layer.

14. The method of producing an anti-reflection film according to claim 8, wherein
the step of forming the second etching mask includes reactive ion etching the transparent material layer.

15. The method of producing an anti-reflection film according to claim 8, wherein
the inorganic material is transition metallic heat sensitive resist made of incomplete oxide of transition metal.
